(19) United States
(12) Patent Application Publication
(10) Pub. No.: US 2024/0096904 A1
(43) Pub. Date: Mar. 21, 2024

(54) CHIP-ON-FILM PACKAGE AND DISPLAY DEVICE INCLUDING THE SAME

(71) Applicant: SAMSUNG ELECTRONICS CO., LTD., SUWON-SI (KR)

(72) Inventors: Jae-Min JUNG, Suwon-si (KR); Seung Hyun CHO, Suwon-si (KR)

(21) Appl. No.: 18/459,766

(22) Filed: Sep. 1, 2023

(30) Foreign Application Priority Data
Sep. 15, 2022 (KR) 10-2022-0116148

(51) Int. Cl. H01L 27/12

(52) U.S. Cl. CPC H01L 27/124

(57) ABSTRACT

A chip-on-film package includes: a lower base film including a first surface and a second surface, which are opposite to each other; an upper base film including a third surface and a fourth surface, which are opposite to each other, and is disposed on the lower base film; a first semiconductor chip mounted on the second surface of the lower base film; a second semiconductor chip mounted on the third surface of the upper base film; and an interposer film interposed between the lower and upper base films, wherein the second and third surfaces face each other.

### CROSS-REFERENCE TO RELATED APPLICATION

This application claims priority under 35 USC § 119 to Korean Patent Application No. 10-2022-0116148 filed on Sep. 15, 2022 in the Korean Intellectual Property Office, the disclosure of which is incorporated by reference herein in its entirety.

### TECHNICAL FIELD

The present inventive concept relates to a chip-on-film (COF) package and a display device including the same.

### DISCUSSION OF THE RELATED ART

Generally, a chip-on-film (COF) package has a structure in which a semiconductor is chip is mounted on a base film. The semiconductor chip may be electrically connected to an external device via a conductive line that is disposed on the base film.

To meet the recent demand for a compact or reduced bezel size and a thin display panel for a display device, one or more semiconductor chips may be mounted in one COF package. For example, when two semiconductor chips are mounted on one base film, at least one conductive line may be formed on the base film, and the semiconductor chips may be at least a predetermined distance apart from one another.

### SUMMARY

According to some exemplary embodiments of the present inventive concept, a chip-on-film package includes: a lower base film including a first surface and a second surface, which are opposite to each other; an upper base film including a third surface and a fourth surface, which are opposite to each other, and is disposed on the lower base film; a first semiconductor chip mounted on the second surface of the lower base film; a second semiconductor chip mounted on the third surface of the upper base film; and an interposer film interposed between the lower and upper base films, wherein the second and third surfaces face each other.

According to some exemplary embodiments of the present inventive concept, a chip-on-film package includes: a lower base film including a first surface and a second surface, which are opposite to each other; lower conductive lines disposed on the second surface of the lower base film; a first semiconductor chip disposed on the lower conductive lines; an upper base film to including a third surface and a fourth surface, wherein the third surface faces the second surface of the lower base film, and the fourth surface is opposite to the third surface; upper conductive lines disposed on the third surface of the upper base film; a second semiconductor chip disposed on the upper conductive lines and overlapping with the first semiconductor chip in a horizontal direction, wherein the second semiconductor chip does not overlap with the first semiconductor is chip in a vertical direction; an interposer film interposed between the lower and upper base films and including a top surface and a bottom surface, which are opposite to each other; first interposer conductive lines disposed on the top surface of the interposer film and connected to the upper conductive lines; and second interposer conductive lines disposed on the bottom surface of the interposer film and connected to the lower conductive lines, wherein the first interposer conductive lines and the upper conductive lines are connected to a first anisotropic conductive layer, the second interposer conductive lines and the lower conductive lines are connected to a second anisotropic conductive layer, and a length, in the horizontal direction, of the lower base film is different from a length, in the horizontal direction, of the upper base film.

According to some exemplary embodiments of the present inventive concept, a display device includes: a chip-on-film package; a driver printed circuit board disposed on a first side of the chip-on-film package; and a display panel disposed at a second side of the chip-on-film package and including a plurality of panel connection lines, which are connected to the chip-on-film package, wherein the chip-on-film package includes: a lower base film including a first surface and a second surface, which are opposite to each other, an upper base film including a third surface and a fourth surface, which are opposite to each other; a first semiconductor chip mounted on the second surface of the lower base film; a second semiconductor chip mounted on the third surface of the upper base film; and an interposer film interposed between the lower base film and the upper base film, wherein the second surface and third surface face each other, and wherein the panel connection lines extend in one direction on the display panel.

### BRIEF DESCRIPTION OF THE DRAWINGS

The above and features of the present inventive concept will become more apparent by describing in detail exemplary embodiments thereof with reference to the attached drawings, in which:

FIG. 1 is a perspective view of a display device according to some exemplary embodiments of the present inventive concept.

FIGS. 2 and 3 are plan views of a COF package according to some exemplary embodiments of the present inventive concept.

FIG. 4 is a cross-sectional view of the COF package of FIGS. 2 and 3.

FIG. 5 is a cross-sectional view of a display device according to some exemplary embodiments of the present inventive concept.

FIG. 6 is a plan view of the display device of FIG. 5.

FIGS. 7 and 8 illustrate COF packages according to some exemplary embodiments of the present inventive concept.

FIGS. 9, 10 and 11 illustrate display devices according to some exemplary embodiments of the present inventive concept.

FIG. 12 illustrates a display device according to some exemplary embodiments of the present inventive concept.

### DETAILED DESCRIPTION

It is to be understood that the present inventive concept may, however, be embodied in different forms and thus should not be construed as being limited to the exemplary embodiments set forth herein.

It will be understood that, although the terms “first,” “second,” etc. may be used herein to describe various elements, these elements should not be limited by these terms. These terms are only used to distinguish one element from another. Thus, a “first” element discussed below could also be termed a “second” element without departing from the spirit and scope of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, in the example, terms “below” and “beneath” may encompass both an orientation of above, below and beneath. The device may be otherwise oriented (e.g., rotated 90 degrees or at other orientations) and the spatially relative descriptors used herein may be interpreted accordingly.

Exemplary embodiments of the present inventive concept will hereinafter be described with reference to the accompanying drawings.

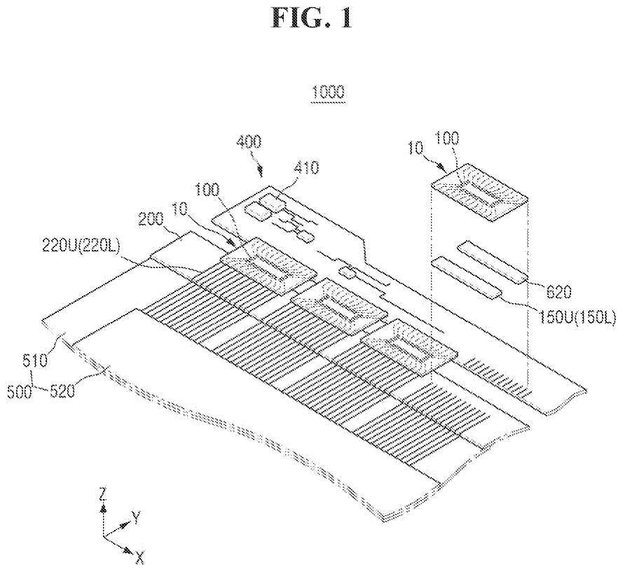

FIG. 1 is a perspective view of a display device according to some exemplary embodiments of the present inventive concept.

Referring to FIG. 1, a display device 1000 may include one or more chip-on-film (COF) packages 10, a driver printed circuit board (PCB) 400, and a display panel 500.

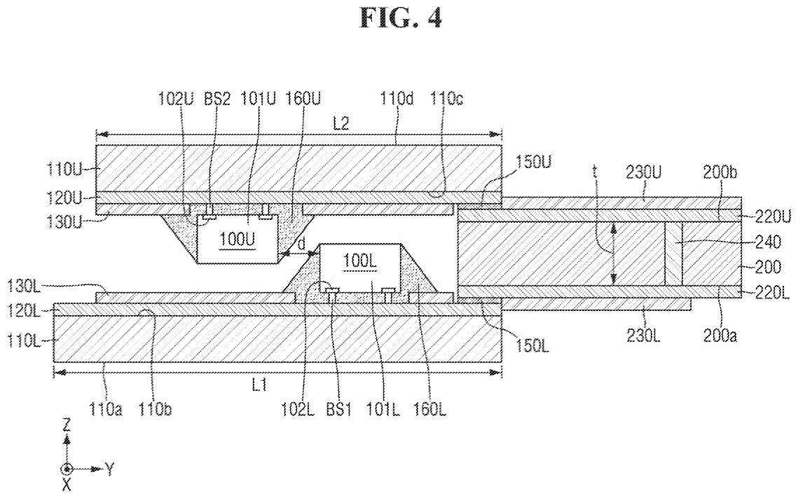

The COF packages 10 may be package including semiconductor chips 100, which are display driver integrated circuits (DDIs). In some exemplary embodiments of the present inventive concept, at least one semiconductor chip 100 may be disposed in each of the COF to packages 10. For example, the semiconductor chips 100 may include source driver chips and/or gate driver chips. In a case where two semiconductor chips 100, for example, first and second semiconductor chips 100L and 100U of FIG. 4, are provided in each of the COF packages 10, the first and second semiconductor chips 100L and 100U may be a source driver chip and a gate driver chip, respectively, but the present inventive concept is not limited thereto. In addition, is the first and second semiconductor chips 100L and 100U may be a gate driver chip and a source driver chip, respectively.

The COF packages 10 may be positioned between the driver PCB 400 and the display panel 500 and may be connected to the driver PCB 400 and the display panel 500. The COF packages 10 may receive signals from the driver PCB 400 and may transmit the received signals to the display panel 500.

In some exemplary embodiments of the present inventive concept, each of the COF packages 10 may further include an interposer film 200. The interposer film 200 may be interposed between the display panel 500 and lower and upper base films (110L and 110U of FIG. 4) that will be described later. The semiconductor chips 100 and the display panel 500 may be connected to each other through the interposer film 200.

One or more driver circuit chips 410, which simultaneously or sequentially apply power and signals to the COF packages 10, may be mounted on the driver PCB 400.

The display panel 500 may be, for example, a liquid crystal display (LCD) panel, a light-emitting diode (LED) Display panel, an organic LED (OLED) display panel, a plasma display panel (PDP), a quantum-dot LED (QLED) display panel, or a quantum nano-emitting diode (QNED) display panel.

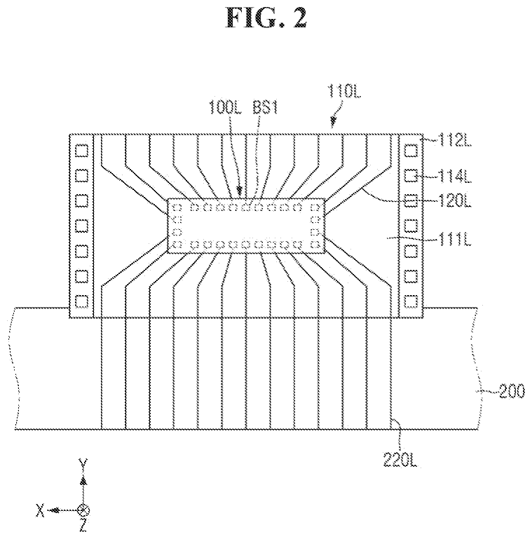

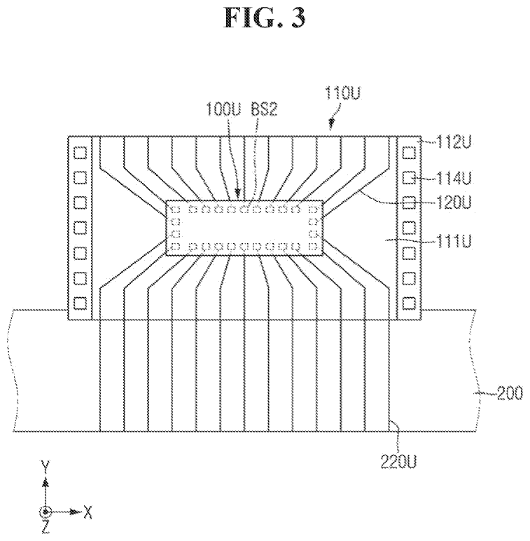

The COF packages 10 may be electrically connected to driving connection lines 430 of the driver PCB 400 and panel connection lines 530 of the display panel 500. The panel connection lines 530 of the display panel 500 may be connected to interposer conductive lines to (220L and 220U), and the driving connection lines 430 of the driver PCB 400 may be connected to conductive lines (120U and 120L of FIGS. 2 and 3) that will be described later.

In some exemplary embodiments of the present inventive concept, one COF package may be connected between the driver PCB 400 and the display panel 500. For example, in a case where the display panel 500 is for providing a small-size screen such as that of a mobile is phone or supports relatively low resolutions, the display device 1000 may include one COF package 10.

In addition, in some exemplary embodiments of the present inventive concept, a plurality of COF packages 10 may be connected between the driver PCB 400 and the display panel 500. For example, in a case where the display panel 500 is for providing a large-size screen such as that of a television (TV) or supports relatively high resolutions, the display device 1000 may include a plurality of COF packages 10.

The display panel 500 may include a transparent substrate 510, an image region 520, which is formed on the transparent substrate 510, and the panel connection lines 530. The transparent substrate 510 may be, for example, a glass substrate or a flexible substrate. A plurality of pixels included in the image region 520 may be connected to their respective panel connection lines 530 and may thus operate in accordance with signals provided to the semiconductor chips 100 on the COF packages 10.

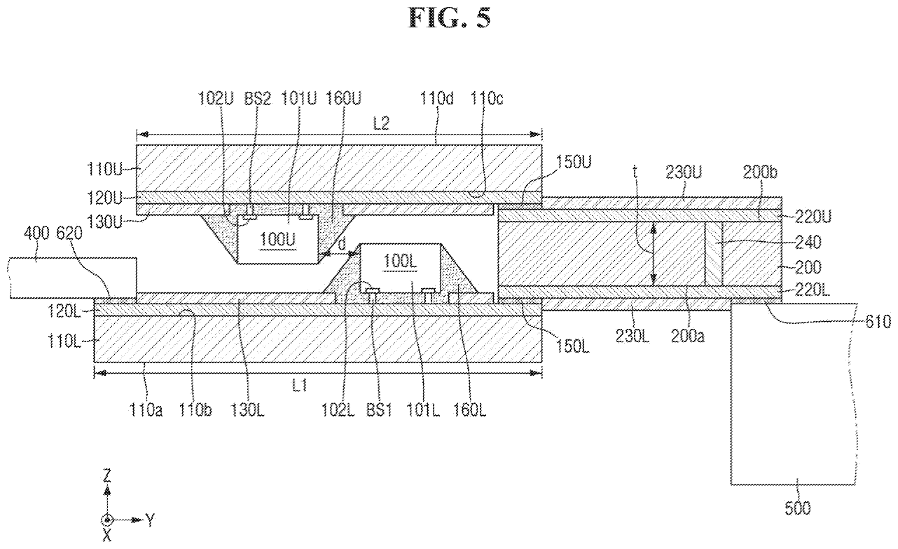

Input pads may be formed at one end of each of the COF packages 10, and output pads may be formed at the other end of each of the COF packages 10. The input pads and the output pads may be connected to the driving connection lines 430 of the driver PCB 400 and the panel connection lines 530 of the display panel 500 via first and second anisotropic conductive layers 610 and 620 of FIG. 5. For example, the first and second anisotropic conductive layers 610 and 620 may be disposed at ends of each of the COF packages 10 and the interposer film 200. The first anisotropic conductive layer 610 may connect the display panel 500 and the COF to packages 10 to each other. The second anisotropic conductive layer 620 may connect the driver PCB 400 and the COF packages 10. However, the present inventive concept is not limited thereto.

In some exemplary embodiments of the present inventive concept, upper and lower anisotropic conductive layers 150U and 150L may be provided. The upper anisotropic is conductive layer 150U is connected to upper conductive lines 120U (of FIG. 3) of each of the COF packages 10. The upper anisotropic conductive layer 150U is connected to first interposer conductive lines 220U of FIG. 3. The lower anisotropic conductive layer 150L is connected to lower conductive lines 120L (of FIG. 2) of each of the COF packages 10. The lower anisotropic conductive layer 150L is connected to second interposer conducive lines 220L.

The first and second anisotropic conductive layers 610 and 620 and the upper and lower anisotropic conductive layers 150U and 150L may be, for example, anisotropic conductive films (ACFs) or anisotropic conductive pastes. The first and second anisotropic conductive layers 610 and 620 and the upper and lower anisotropic conductive layers 150U and 150L may each have a structure in which conductive particles are dispersed in an insulating adhesive layer. The first and second anisotropic conductive layers 610 and 620 and the upper and lower anisotropic conductive layers 150U and 150L may have anisotropic electrical characteristics. Thus, the first and second anisotropic conductive layers 610 and 620 and the upper and lower anisotropic conductive layers 150U and 150L may conduct electricity only in a direction between opposing electrodes (e.g., in a third direction Z) and may be insulated in a direction between neighboring electrodes (e.g., in a first direction X). When an adhesive is melted by applying heat and pressure to the first and second anisotropic conductive layers 610 and the upper and lower anisotropic conductive layers 150U and 150L, the conductive particles in the first and second anisotropic conductive layers 610 and the upper and lower anisotropic conductive layers 150U and 150L may be arranged and conducted between the opposing to electrodes, for example, between the input pads and the drive connection wiring and between the output pads and the panel connection wiring, but the gaps between the neighboring electrodes may be filled with the adhesive and may thus be insulated.

The COF packages 10 included in the display device 1000 will hereinafter be described.

FIGS. 2 and 3 are plan views of a COF package according to some exemplary embodiments of the present inventive concept. FIG. 4 is a cross-sectional view of the COF package of FIGS. 2 and 3.

Specifically, FIG. 2 is a plan view of a COF package according to some exemplary embodiments of the present inventive concept, as viewed from therebelow. FIG. 3 is a plan view of the COF package of FIG. 2, as viewed from thereabove, and FIG. 4 is a cross-sectional view of the COF package of FIG. 2 or 3, as viewed from a side thereof.

Referring to FIGS. 2 through 4, a COF package 10 may include a first semiconductor chip 100L, a second semiconductor chip 100U, a lower base film 110L, an upper base film 110U, and an interposer film 200.

The first and second semiconductor chips 100L and 100U may be DDIs for driving the display device 1000 of FIG. 1. For example, the first semiconductor chip 100L may be generate an image signal based on a data signal from a timing controller and may be a source driver chip outputting the image signal to the display panel 500 of FIG. 1, and the second semiconductor chip 100U may be a gate driver chip outputting a scan signal including an on/off signal for a transistor to the display panel 500 of FIG. 1. In another example, the first semiconductor chip 100L may be a gate driver chip, and the second semiconductor chip 100U may be a source driver chip.

The types of the first and second semiconductor chips 100L and 100U are not to particularly limited. For example, in a case where the COF package 10 is coupled to an electronic device other than the display device 1000, the first and second semiconductor chips 100L and 100U may be chips for driving the electronic device.

For convenience, FIGS. 2 through 4 illustrate that two semiconductor chips, i.e., the first and second semiconductor chips 100L and 100U, are provided, but the number of is semiconductor chips provided is not particularly limited. In some exemplary embodiments of the present inventive concept, the number of source driver chips may be configured to be the same as, or greater than, the number of gate driver chips in consideration of the characteristics of the display device 1000 of FIG. 1.

In some exemplary embodiments of the present inventive concept, each of the first and second semiconductor chips 100L and 100U may have long sides in the first direction X and short sides in a second direction Y. The first, second, and third directions X, Y, and Z may be substantially orthogonal to one another. The third direction Z may be a vertical direction, and the first and second directions X and Y may be horizontal directions. For example, each of the first and second semiconductor chips 100L and 100U may have a rectangular shape. The length of the long sides of each of the first and second semiconductor chips 100L and 100U may be about 1.5 times the length of the short sides of each of the first and second semiconductor chips 100L and 100U. The shape of the first and second semiconductor chips 100L and 100U may be determined to facilitate and improve the layout and the freedom of design of the conductive lines (120L and 120U).

The first semiconductor chip 100L may include a lower substrate 101L and lower bump pads 102L. The lower substrate 101L, which is a semiconductor substrate, may have an active surface and an inactive surface that are opposite to each other. For example, the lower substrate 101L may be a silicon (Si) wafer including crystalline Si, polycrystalline Si, or amorphous Si. In addition, the lower substrate 101L may include an element semiconductor to such as germanium (Ge) or a compound semiconductor such as silicon carbide (SiC), gallium arsenide (GaAs), indium arsenide (InAs), or indium phosphide (InP).

The lower substrate 101L may have a silicon-on-insulator (SoI) structure. In some exemplary embodiments of the present inventive concept, the lower substrate 101L may include a conductive region, for example, a well or structure doped with impurities. In addition, the is lower substrate 101L may have various other structures such as a shallow trench isolation (STI) structure.

The first semiconductor chip 101L may be disposed in a lower circuit region 111L (particularly, a chip mounting region) of the lower base film 101L and may be mounted on the lower base film 110L through flip chip bonding. For example, lower bump structures BS1 such as solder balls may be disposed on the lower bump pads 102L, which are exposed on the active surface of the first semiconductor chip 100L. The first semiconductor chip 100L may be mounted on the lower base film 110L by physically and electrically connecting the lower bump structures BS1 to lower bump pads 102L on the lower base film 110L. Some of the lower bump pads 102L may function as input terminals, and some of the lower bump pads 102L may function as output terminals.

The lower bump structures BS1 may be in contact with the lower bump pads 102L and the lower conductive lines 120L. The first semiconductor chip 100L may receive at least one of a control signal, a power signal, and a ground signal for driving the first semiconductor chip 100L from the outside through the lower bump structures BS1. In addition, the first semiconductor chip 100L may receive a data signal to be stored therein from the outside through the lower bump structures BS1. Further, the first semiconductor chip 100L may provide data stored therein to the outside, through the lower bump structures BS1. For example, the lower bump structures BS1 may be formed as pillars, balls, or solder layers.

The lower base film 110L may be a flexible film including polyimide, which has an to excellent coefficient of thermal expansion (CTE) and durability, but the present inventive concept is not necessarily limited thereto. In addition, the lower base film 110L may be formed of a synthetic resin such as an epoxy resin, acrylic, polyether nitrile, polyether sulfone, polyethylene terephthalate, or polyethylene naphthalate.

The lower base film 110L may include the lower circuit region 111L, which is is disposed in the middle of the lower base film 110L, and lower perforation regions 112L, which are disposed at both ends (e.g., opposing sides) of the lower circuit region 111L. The lower circuit region 111L may be a region where the first semiconductor chip 100L is mounted.

The lower perforation regions 112L may be positioned at both ends of the lower base film 110L and may include a plurality of lower perforation holes 114L. The reeling of the lower base film 110L onto a winding reel may be controlled through the lower perforation holes 114L. The unreeling of the lower base film 110L from the winding reel may also be controlled through the lower perforation holes 114L.

As the pitch of the lower perforation holes 114L is uniform, the length of the lower base film 110L may be determined by the number of lower perforation holes 114L. The width and the length of the lower base film 110L may also be determined by the number and size of first semiconductor chips 100L mounted on the lower perforation holes 114L and the layout of the lower conductive lines 120L on the lower base film 110L.

The lower perforation regions 112L may be cut away from the lower base film 110L before the placement of the COF package 10 in the display device 1000 of FIG. 1. That is, eventually, only the lower circuit region 111L may be disposed in the display device 1000 of FIG. 1.

In some exemplary embodiments of the present inventive concept, the lower base film 110L may have first and second surfaces 110a and 110b, which are opposite to each other. The lower conductive lines 120L may be disposed on the second surface 110b of the lower base to film 110L. The second surface 110b of the lower base film 110L may face the upper base film 110U. The lower conductive lines 120L may be formed of, for example, an aluminum (Al) foil or a copper (Cu) foil. In some exemplary embodiments of the present inventive concept, the lower conductive lines 120L may be formed by forming a metal layer formed on the lower base film 110L and patterning the metal layer through casting, lamination, or electroplating.

In some exemplary embodiments of the present inventive concept, lower conductive pads may be formed at parts of the lower conductive lines 120L. The lower conductive pads may be parts of the lower conductive lines 120L or may be obtained by plating parts of the lower conductive lines 120L with, for example, tin (Sb), gold (Au), nickel (Ni), or lead (Pb). In some exemplary embodiments of the present inventive concept, the lower conductive pads are electrically connected to the lower conductive lines 120L. The lower conductive pads may face, and be electrically connected to, the lower bump pads 102L of the first semiconductor chip 100L.

In some exemplary embodiments of the present inventive concept, a lower protective member 130L may be formed on the lower conductive lines 120L. The lower protective member 130L may be formed to protect the lower conductive lines 120L from the outside to prevent physical and/or chemical damage. The lower protective member 130L may cover the lower conductive lines 120L while partially exposing the lower conductive lines 120L. For example, the lower protective member 130L may expose a portion of the lower conductive lines 120L. The lower protective member 130L may be formed of, for example, solder resist or dry film resist, but the present inventive concept is not limited thereto. In addition, the lower protective member 130L may be formed of a silicon oxide- or silicon nitride-based insulating layer.

In some exemplary embodiments of the present inventive concept, a lower underfill 160L may cover the lower bump structures BS1 and the sidewalls of the first semiconductor chip 100L. The lower underfill 160L may fill the space between the lower conductive lines 120L to and the first semiconductor chip 100L. The lower underfill 160L may protect the lower bump structures BS1 and their surroundings from the outside to prevent physical and/or chemical damage. The lower underfill 160L may be formed by a capillary underfill process. The lower underfill 160L may be formed of, for example, an epoxy resin, but the present inventive concept is not necessarily limited thereto.

The second semiconductor chip 100U may include an upper substrate 101U and upper bump pads 102U. The upper substrate 101U, which is a semiconductor substrate, may have an active surface and an inactive surface that are opposite to each other. For example, the upper substrate 101U may be a Si wafer including crystalline Si, polycrystalline Si, or amorphous Si. In addition, the upper substrate 101U may include an element semiconductor such as Ge or a compound semiconductor such as SiC, GaAs, InAs, or InP.

The upper substrate 101U may have an SoI structure. In some exemplary embodiments of the present inventive concept, the upper substrate 101U may include a conductive region, for example, a well or structure doped with impurities. In addition, the upper substrate 101U may have various other structures such as a STI structure.

The second semiconductor chip 100U may be disposed in an upper circuit region 111U (particularly, a chip mounting region) of the upper base film 110U and may be mounted on the upper base film 110U through flip chip bonding. In other words, upper bump structures BS2 such as solder balls may be disposed on the upper bump pads 102U, which are exposed on the active surface of the second semiconductor chip 100U. The second semiconductor chip 100U may be mounted on the upper base film 110U by physically and electrically connecting the upper bump structures BS2 to upper bump pads 102U. Some of the upper bump pads 102U may function as input terminals, and some of the upper bump pads 102U may function as output terminals.

In some exemplary embodiments of the present inventive concept, a distance, in a horizontal direction, between the first and second semiconductor chips 100L and 100U may be about 6 mm or less. For example, a distance d, in the second direction Y, between the first and second semiconductor chips 100L and 100U may be about 6 mm or less. As the distance between the first and second semiconductor chips 100L and 100U decreases, the size of the COF is package 10 can be reduced accordingly.

In some exemplary embodiments of the present inventive concept, the first and second semiconductor chips 100L and 100U might not overlap with each other in the third direction Z. At least part of the second semiconductor chip 100U may overlap horizontally with the first semiconductor chip 100L. For example, at least part of the second semiconductor chip 100U may overlap with the first semiconductor chip 100L in the second direction Y.

The upper bump structures BS2 may be in contact with the upper bump pads 102U and the upper conductive lines 120U. The second semiconductor chip 100U may receive at least one of a control signal, a power signal, and/or a ground signal for driving the second semiconductor chip 100U from the outside through the upper bump structures BS2. In addition, the second semiconductor chip 100U may receive a data signal to be stored therein from the outside through the upper bump structures BS2. Further, the second semiconductor chip 100U may provide data stored therein to the outside, through the upper bump structures BS2. For example, the lower bump structures BS1 may be formed as pillars, balls, or solder layers.

The upper base film 110U may be disposed on the lower base film 101L. The upper base film 110U may be spaced apart from the lower base film 110L in the third direction Z. The upper base film 110U may have third and fourth surfaces 110c and 110d, which are opposite to each other. The third surface 110c of the upper base film 110U may face the lower base film 110L.

In some exemplary embodiments of the present inventive concept, a length L1, in to the second direction Y, of the lower base film 110L may be greater than a length L2, in the second direction Y, of the upper base film 110U. The lower conductive lines 120L and the driver PCB 400 of FIG. 5 may be connected to each other on the lower base film 101L. As space for connection to the driver PCB 400 needs to be secured, the length L1, in the second direction Y, of the lower base film 110L may be greater than the length L2, in the second is direction Y, of the upper base film 110U.

The upper base film 110U may be a flexible film including polyimide, which has an excellent CTE and durability, but the present inventive concept is not necessarily limited thereto. In addition, the upper base film 110U may be formed of a synthetic resin such as an epoxy resin, acrylic, polyether nitrile, polyether sulfone, polyethylene terephthalate, or polyethylene naphthalate.

The upper base film 110U may include the upper circuit region 111U, which is disposed in the middle of the upper base film 110U, and upper perforation regions 112U, which are disposed at both ends (e.g., opposing sides) of the upper circuit region 111U. The upper circuit region 111U may be a region where the second semiconductor chip 100U is mounted.

The upper perforation regions 112U may be positioned at both ends of the upper base film 110U and may include a plurality of upper perforation holes 114U. The reeling of the upper base film 110U onto a winding reel may be controlled through the upper perforation holes 114L. The unreeling of the upper base film 110U from the winding reel may also be controlled through the upper perforation holes 114U.

As the pitch of the upper perforation holes 114U is uniform, the length of the upper base film 110U may be determined by the number of upper perforation holes 114U. The width and the length of the upper base film 110U may also be determined by the number and size of second semiconductor chips 100U mounted on the upper perforation holes 114U and the layout to of the upper conductive lines 120U on the upper base film 110U.

The upper perforation regions 112U may be cut away from the upper base film 110U before the placement of the COF package 10 in the display device 1000 of FIG. 1. That is, eventually, only the upper circuit region 111U may be disposed in the display device 1000 of FIG. 1.

In some exemplary embodiments of the present inventive concept, the upper conductive lines 120U may be disposed on the second surface 110b of the lower base film 110L. The second surface 110b of the lower base film 110L may face the upper base film 110U. The upper conductive lines 120U may be formed of, for example, an Al foil or a Cu foil. In some exemplary embodiments of the present inventive concept, the upper conductive lines 120U may be formed by forming a metal layer formed on the upper base film 110U and patterning the metal layer through casting, lamination, or electroplating.

In some exemplary embodiments of the present inventive concept, upper conductive pads may be formed at parts of the upper conductive lines 120U. The upper conductive pads may be parts of the upper conductive lines 120U or may be obtained by plating parts of the upper conductive lines 120U with, for example, Sb, Au, Ni, or Pb. In some exemplary embodiments of the present inventive concept, the upper conductive pads are electrically connected to the upper conductive lines 120U. The upper conductive pads may face, and be electrically connected to, the upper bump pads 102U of the second semiconductor chip 100U.

In some exemplary embodiments of the present inventive concept, an upper protective member 130U may be formed on the upper conductive lines 120U. The upper protective member 130U may be formed to protect the upper conductive lines 120U from the outside to prevent physical and/or chemical damage. The upper protective member 130U may cover the upper conductive lines 120U while partially exposing the upper conductive lines 120U. For example, the upper protective member 130U may expose a portion of the upper conductive to lines 120U. The upper protective member 130U may be formed of, for example, solder resist or dry film resist, but the present inventive concept is not necessarily limited thereto. In addition, the upper protective member 130U may be formed of a silicon oxide- or silicon nitride-based insulating layer.

In some exemplary embodiments of the present inventive concept, an upper underfill 160U may cover the upper bump structures BS2 and the sidewalls of the second semiconductor chip 100U. The upper underfill 160U may fill the space between the upper conductive lines 120U and the second semiconductor chip 100U. The upper underfill 160U may protect the upper bump structures BS2 and their surroundings from the outside to prevent physical and/or chemical damage. The upper underfill 160U may be formed by a capillary underfill process. The upper underfill 160U may be formed of, for example, an epoxy resin, but the present inventive concept is not necessarily limited thereto.

In some exemplary embodiments of the present inventive concept, the interposer film 200 may be interposed between the lower and upper base films 110L and 110U.

At least part of the interposer film 200 may overlap with the lower and upper base films 110L and 110U in the third direction Z. Another part of the interposer film 200 might not overlap with the lower and upper base films 110L and 110U in the third direction Z. For example, at least part of the interposer film 200 may be disposed in the space between the lower and upper base films 110L and 110U.

The interposer film 200 may have bottom and top surfaces 200a and 200b, which are opposite to each other. The bottom surface 200a of the interposer film 200 may face the second surface 110b of the lower base film 110L. The top surface 200b of the interposer film 200 may face the third surface 110c of the upper base film 110U.

In some exemplary embodiments of the present inventive concept, a thickness t, in the third direction Z, of the interposer film 200 may be about 30 μm to about 40 μm, but the to present inventive concept is not necessarily limited thereto.

The interposer film 200 may be a flexible film including polyimide, which has an excellent CTE and durability, but the present inventive concept is not necessarily limited thereto. In addition, the interposer film 200 may be formed of a synthetic resin such as an epoxy resin, acrylic, polyether nitrile, polyether sulfone, polyethylene terephthalate, or polyethylene is naphthalate.

In some exemplary embodiments of the present inventive concept, the first interposer conductive lines 220U may be disposed on the top surface 200b of the interposer film 200. The second interposer conductive lines 220L may be disposed on the bottom surface 200a of the interposer film 200.

The first interposer conductive lines 220U may be connected to the upper conductive lines 120U. For example, an upper anisotropic conductive layer 150U may be formed between the first interposer conductive lines 220U and the upper conductive lines 120U. The upper anisotropic conductive layer 150U may conduct electricity in the third direction Z and may be insulated in the first direction X and/or the second direction Y. The second interposer conductive lines 220L may be connected to the lower conductive lines 120L. For example, a lower anisotropic conductive layer 150L may be formed between the second interposer conductive lines 220L and the lower conductive lines 120L. The lower anisotropic conductive layer 150L may conduct electricity in the third direction Z and may be insulated in the first direction X and/or the second direction Y.

The first interposer conductive lines 220U and the second interposer conductive lines 220L may be formed of, for example, an Al foil or a Cu foil. The first interposer conductive lines 220U and the second interposer conductive lines 220L may be formed by forming a metal layer on the bottom or top surface 200a or 200b of the interposer film 200 and patterning the metal layer through casting, lamination, or electroplating.

In some exemplary embodiments of the present inventive concept, interposer vias 240 may be formed in the interposer film 200. The interposer vias 240 may penetrate from the top surface 200b to the bottom surface 200a of the interposer film 200. The interposer vias 240 may be electrically connected to the first interposer conductive lines 220U and the second interposer conductive lines 220L. The interposer vias 240 may be formed of a conductive material. For example, the interposer vias 240 may be formed of Cu or Al, but the present disclosure is not limited thereto.

A first interposer protective member 230U may be disposed on the first interposer conductive lines 220U. The first interposer protective member 230U may protect the first interposer conductive lines 220U from the outside to prevent physical and chemical damage. The first interposer protective member 230U may expose parts of the first interposer conductive lines 220U. The upper anisotropic conductive layer 150U may be disposed on the exposed parts of the first interposer conductive lines 220U. The upper conductive lines 120U may be disposed on the upper anisotropic conductive layer 150U.

A second interposer protective member 230L may be disposed on the second interposer conductive lines 220L. The second interposer protective member 230L may protect the second interposer conductive lines 220L from the outside to prevent physical and chemical damage. The second interposer protective member 230L may expose parts of the second interposer conductive lines 220L. The lower anisotropic conductive layer 150L may be disposed on the exposed parts of the second interposer conductive lines 220L. The lower conductive lines 120L may be disposed on the lower anisotropic conductive layer 150L.

The first and second interposer protective members 230U and 230L may be formed of, for example, solder resist or dry film resist, but the present inventive concept is not necessarily limited thereto. In addition, the first and second interposer protective members 230U and 230L may be formed of, for example, a silicon oxide- or silicon nitride-based to insulating layer.

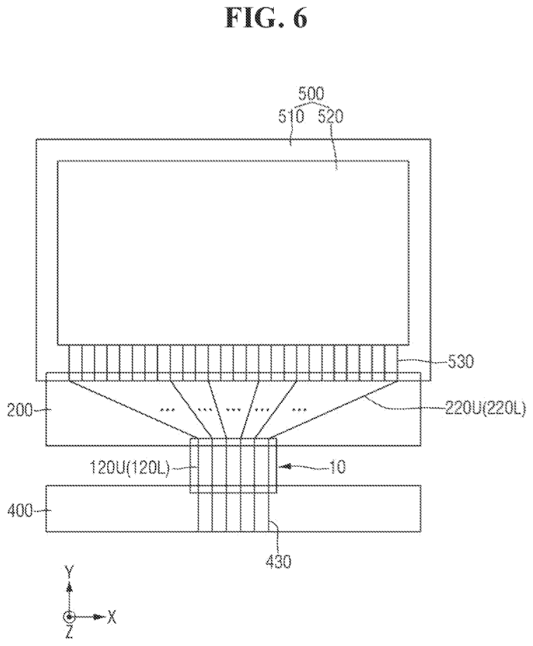

FIG. 5 is a cross-sectional view of a display device according to some exemplary embodiments of the present inventive concept. FIG. 6 is a plan view of the display device of FIG. 5. For convenience, the embodiment of FIGS. 5 and 6 will hereinafter be described, focusing mainly on the differences with the embodiment of FIGS. 1 through 4.

Referring to FIG. 5, a driver PCB 400 may be connected to one end of a COF package. A display panel 500 may be connected to the other end of the COF package. The diver PCB 400 may be connected to lower conductive lines 120L. A second anisotropic conductive layer 620 may be disposed between the lower conductive lines 120L and the driver PCB 400. As already mentioned above, the second anisotropic conductive layer 620 may conduct electricity in a third direction Z and may be insulated in a first direction X and/or in a second direction Y.

The display panel 500 may be connected to second interposer conductive lines 220L. A first anisotropic conductive layer 610 may be disposed between the second interposer conductive lines 220L and the display panel 500. As already mentioned above, the first anisotropic conductive layer 610 may conduct electricity in the third direction Z and may be insulated in the first direction X and/or in the second direction Y.

In some exemplary embodiments of the present inventive concept, the length of a second interposer protective member 230L may be less than the length of a first interposer protective member 230U to secure space in which the first anisotropic conductive layer 610 is disposed, but the present inventive concept is not necessarily limited thereto.

Referring to FIG. 6, panel connection lines 530 of the display panel 500 extend in the second direction Y. For example, the panel connection lines 530 do not extend in an arbitrary direction between the first and second directions X and Y, in the display panel 500. For example, the panel connection lines 530 do not extend in a diagonal direction between the first and second directions X and Y. The panel connection lines 530 may extend in one direction in the display panel 500. Accordingly, a display device with increased reliability can be realized.

Some of the first interposer conductive lines 220U and/or some of the second is interposer conductive lines 220L may extend in an arbitrary direction between the first and second directions X and Y. In some exemplary embodiments of the present inventive concept, in a case where the display device supports relatively low resolutions, the display device may include one COF package, in which case, the length, in the first direction X, of the COF package may be less than the length, in the first direction X, of the display panel 500. To connect the panel connection lines 530 of the display panel 500 and conductive lines (120U and 120L) of the COF package, the first interposer conductive lines 220U and the second interposer conductive lines 220L, which connect the panel connection lines 530 and the conductive lines (120U and 120L), need to extend in a direction between the first and second directions X and Y.

As the display device further includes an interposer film 200, the panel connection lines 530 may be able to extend in one direction. Accordingly, a display device with increased reliability can be realized.

In some exemplary embodiments of the present inventive concept, the width, in the first direction X, of the interposer film 200 may be about 35 mm to about 156 mm, but the present inventive concept is not necessarily limited thereto.

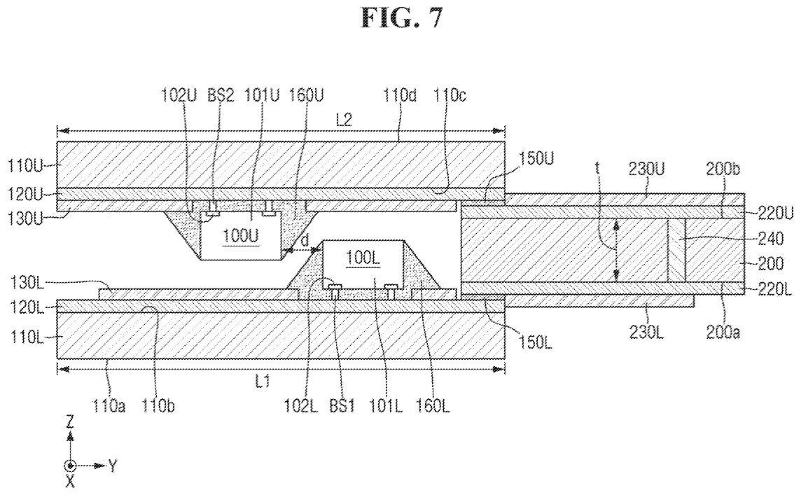

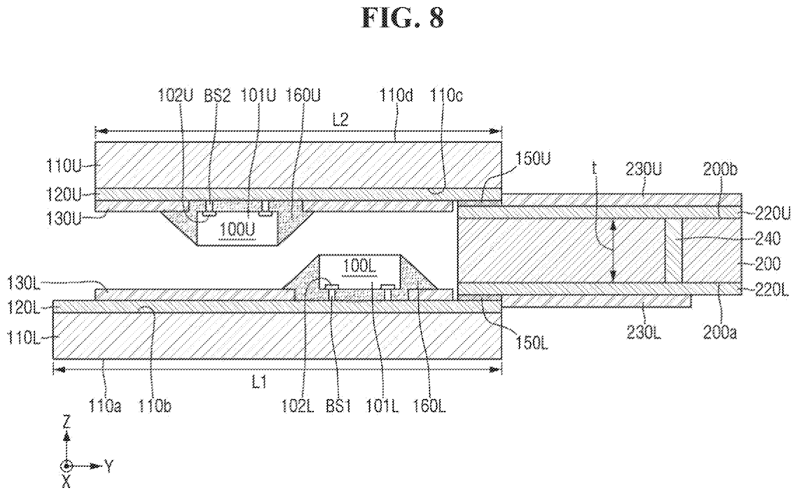

FIGS. 7 and 8 illustrate COF packages according to some exemplary embodiments of the present inventive concept. For convenience, the embodiments of FIGS. 7 and 8 will hereinafter be described, focusing mainly on the differences with the embodiment of FIGS. 1 through 4. FIGS. 7 and 8 are cross-sectional views of COF packages according to some exemplary embodiments of the present inventive concept, as viewed from sides thereof.

Referring to FIG. 7, a length L1, in a second direction Y, of a lower base film 110L may be the same as a length L2, in the second direction Y, of an upper base film 110U. Accordingly, the length of lower conductive lines 120L, which are disposed on a second surface 110b of the lower base film 110L, may be the same as the length of upper conductive lines 120U, which are disposed on a third surface 110c of the upper base film 110U.

Referring to FIG. 8, first and second semiconductor chips 100L and 100U might not overlap with each other in a horizontal direction. As the first and second semiconductor chips 100L and 100U are miniaturized, the height, in a third direction Z, of the first and second semiconductor chips 100L and 100U may be reduced. In this case, the first and second semiconductor chips 100L and 100U might not overlap with each other in a first direction X and/or a second direction Y.

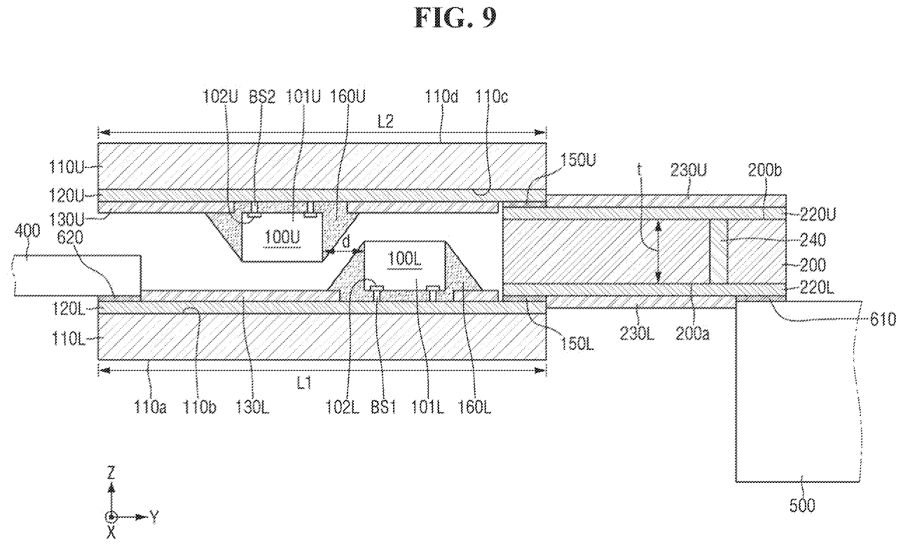

FIGS. 9 through 11 illustrate display devices according to some exemplary embodiments of the present inventive concept. For convenience, the embodiments of FIGS. 9 through 11 will hereinafter be described, focusing mainly on the differences with the embodiment of FIG. 5.

Referring to FIG. 9, a length L1, in a second direction Y, of a lower base film 110L may be the same as a length L2, in the second direction Y, of an upper base film 110U. In this case, at least part of a driver PCB 400, which is connected to lower conductive lines 120L on the lower base film 110L, may overlap with the upper base film 110U in a third direction Z.

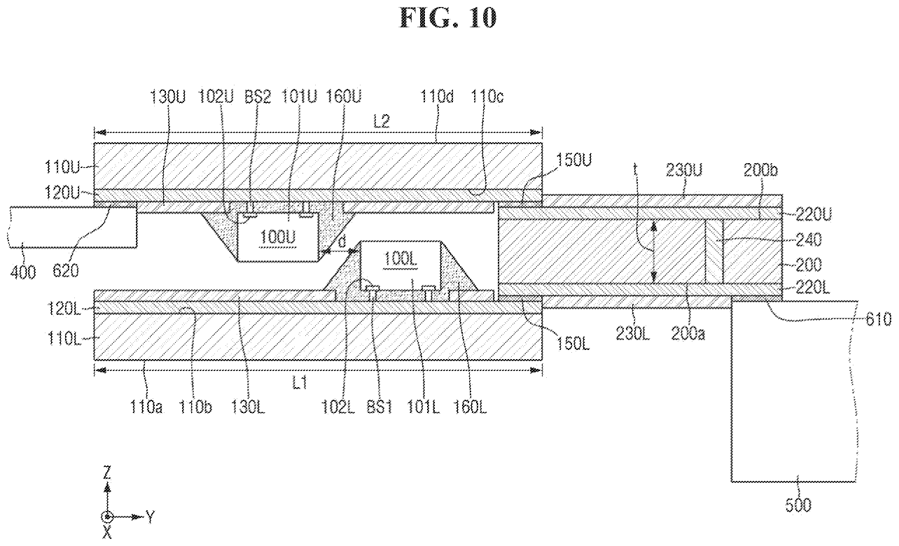

Referring to FIG. 10, a driver PCB 400 may be connected to upper conductive lines 120U. A second anisotropic conductive layer 620 may be disposed between the upper conductive lines 120U and the driver PCB 400. A length L1, in a second direction Y, of a to lower base film 110L may be the same as a length L2, in the second direction Y, of an upper base film 110U. Accordingly, at least part of the driver PCB 400, which is connected to the upper conductive lines 120U on the upper base film 110U, may overlap with the lower base film 110L in a third direction Z.

In some exemplary embodiments of the present inventive concept, a lower is protective member 130L may expose first end portions of lower conductive lines 120L, but not second end portions of the lower conductive lines 120L. In addition, an upper protective member 130U may expose both first end portions and second end portions of the upper conductive lines 120U. The exposed first end portions of the lower conductive lines 120L are connected to second interposer conductive lines 220L. The exposed first end portions of the upper conductive lines 120U are connected to first interposer conductive lines 220U. The exposed second end portions of the upper conductive lines 120U are connected to the driver PCB 400.

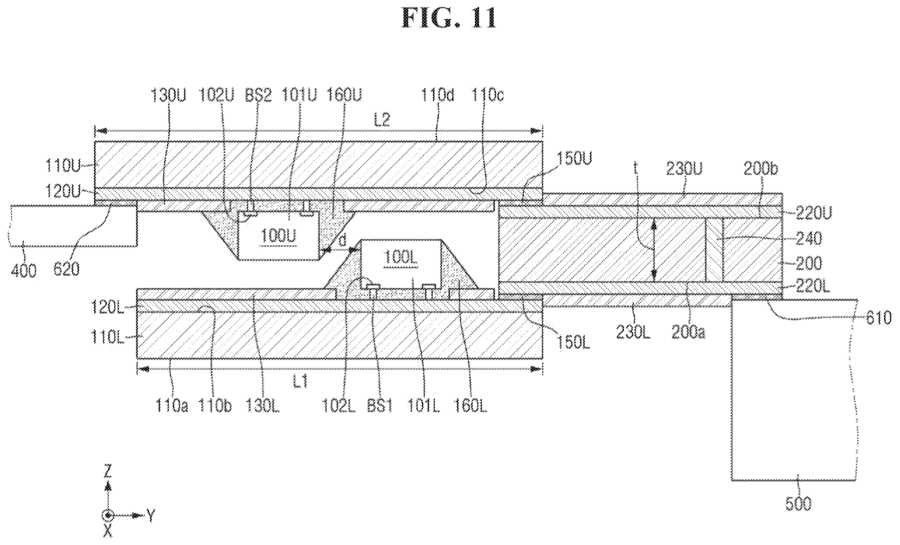

Referring to FIG. 11, a length L1, in a second direction Y, of a lower base film 110L may differ from a length L2, in the second direction Y, of an upper base film 110U. For example, the length L1, in the second direction Y, of the lower base film 110L may be greater than the length L2, in the second direction Y, of the upper base film 110U. A driver PCB 400 may be connected to upper conductive lines 120U. In this case, the driver PCB 400 might not overlap with the lower base film 110L in a third direction Z, but the present inventive concept is not limited thereto.

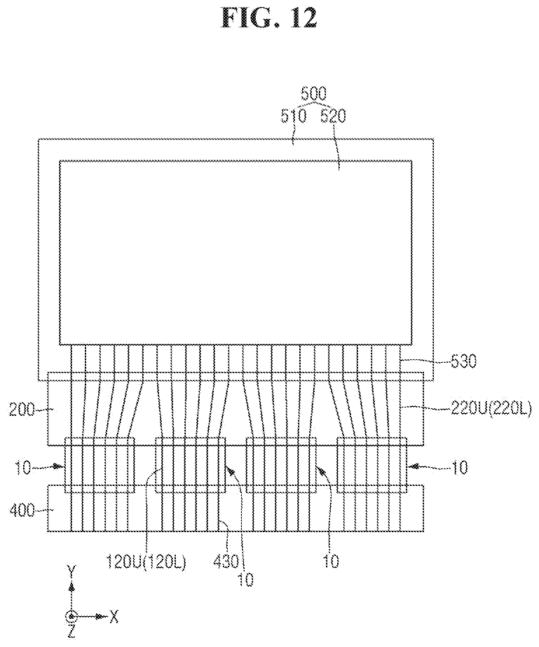

FIG. 12 illustrates a display device according to some exemplary embodiments of the present inventive concept. For convenience, the embodiment of FIG. 12 will hereinafter be described, focusing mainly on the differences with the embodiment of FIG. 6.

Referring to FIG. 12, the display device may include a plurality of COF packages 10. For example, in a case where a display panel 500 is for providing a large-size screen such as that to of a television (TV) and/or supports relatively high resolutions, a plurality of COF packages 10 may be disposed on one side of the display panel 500.

In the embodiment of FIG. 12, like in the previous embodiments, panel connection lines 530 of the display panel 500 extend in a second direction Y, but not in an arbitrary direction between a first direction X and the second direction Y. The panel connection lines 530 may is extend in one direction. Accordingly, a display device with increased reliability can be realized.

Some of first interposer conductive lines 220U and/or some of second interposer conductive lines 220L may extend in a direction between the first and second directions X and Y, and some of the first interposer conductive lines 220U and/or some of the second interposer conductive lines 220L may extend in the second direction Y.

As the display device further includes an interposer film 200, the panel connection lines 530 may be able to extend in one direction. Accordingly, a display device with increased reliability can be realized.

While the present inventive concept has been described with reference to exemplary embodiments thereof, it will be understood by those of ordinary skill in the art that various changes in form and details may be made thereto without departing from the spirit and scope of the present inventive concept.

What is claimed is:

1. A chip-on-film package, comprising:
a lower base film including a first surface and a second surface, which are opposite to each other;
an upper base film including a third surface and a fourth surface, which are opposite to each other, and is disposed on the lower base film;
a first semiconductor chip mounted on the second surface of the lower base film;
a second semiconductor chip mounted on the third surface of the upper base film; and
an interposer film interposed between the lower and upper base films,
wherein the second and third surfaces face each other.

2. The chip-on-film package of claim 1, wherein the first semiconductor chip and the second semiconductor chip do not overlap with each other in a vertical direction with respect to the second surface of the lower base film.

3. The chip-on-film package of claim 2, wherein at least part of the first semiconductor chip overlaps with the second semiconductor chip in a horizontal direction, which intersects the vertical direction.

4. The chip-on-film package of claim 1, wherein a distance, in a horizontal direction, between the first semiconductor chip and the second semiconductor chip is about 6 mm or less.

5. The chip-on-film package of claim 1, wherein a thickness, in a vertical direction with respect to the second surface of the lower base film, of the interposer film is about 30 μm to about 40 μm.

6. The chip-on-film package of claim 1, further comprising:
lower conductive lines disposed on the second surface of the lower base film; and
upper conductive lines disposed on the third surface of the upper base film.

7. The chip-on-film package of claim 1, further comprising:
to a lower protective member covering at least portions of the lower conductive lines; and
an upper protective member covering at least portions of the upper conductive lines.

8. The chip-on-film package of claim 6, wherein the interposer film includes a top is surface and a bottom surface, which are opposite to each other, and further includes first interposer conductive lines and second interposer conductive lines, wherein the first interposer conductive lines are disposed on the top surface of the interposer film and are connected to the upper conductive lines, and wherein the second interposer conductive lines are disposed on the bottom surface of the interposer film and are connected to the lower conductive lines.

9. The chip-on-film package of claim 8, further comprising:
interposer vias penetrating the interposer film and connecting the first interposer conductive lines to the second interposer conductive lines.

10. The chip-on-film package of claim 1, wherein a width of the interposer film is about 35 mm to about 156 mm.

11. The chip-on-film package of claim 1, wherein a length of the upper base film is different from a length of the lower base film.

12. A chip-on-film package comprising:
a lower base film including a first surface and a second surface, which are opposite to each other;
lower conductive lines disposed on the second surface of the lower base film;
a first semiconductor chip disposed on the lower conductive lines;
an upper base film including a third surface and a fourth surface, wherein the third surface faces the second surface of the lower base film, and the fourth surface is opposite to the third surface;
upper conductive lines disposed on the third surface of the upper base film;
a second semiconductor chip disposed on the upper conductive lines and overlapping with the first semiconductor chip in a horizontal direction, wherein the second semiconductor chip does not overlap with the first semiconductor chip in a vertical direction;
an interposer film interposed between the lower and upper base films and including a top surface and a bottom surface, which are opposite to each other;
first interposer conductive lines disposed on the top surface of the interposer film and connected to the upper conductive lines; and
second interposer conductive lines disposed on the bottom surface of the interposer film and connected to the lower conductive lines,
wherein
the first interposer conductive lines and the upper conductive lines are connected to a first anisotropic conductive layer,
the second interposer conductive lines and the lower conductive lines are connected to a second anisotropic conductive layer, and
a length, in the horizontal direction, of the lower base film is different from a length, in the horizontal direction, of the upper base film.

13. The chip-on-film package of claim 12, wherein a distance, in the horizontal direction, between the first semiconductor chip and the second semiconductor chip is about 6 to mm or less.

14. The chip-on-film package of claim 12, wherein a thickness, in the vertical direction, of the interposer film is about 30 μm to about 40 μm.

15. The chip-on-film package of claim 12, wherein a width of the interposer film is about 35 mm to about 156 mm.

16. A display device comprising:
a chip-on-film package;
a driver printed circuit board disposed on a first side of the chip-on-film package; and
a display panel disposed at a second side of the chip-on-film package and including a plurality of panel connection lines, which are connected to the chip-on-film package,
wherein
the chip-on-film package includes:
a lower base film including a first surface and a second surface, which are opposite to each other;
an upper base film including a third surface and a fourth surface, which are opposite to each other;
a first semiconductor chip mounted on the second surface of the lower base film;
a second semiconductor chip mounted on the third surface of the upper base film; and
an interposer film interposed between the lower base film and the upper base film,
wherein the second surface and third surface face each other, and
to wherein the panel connection lines extend in one direction on the display panel.

17. The display device of claim 16, wherein the interposer film is interposed between the lower base film and the display panel.

18. The display device of claim 16, wherein a distance, in a horizontal direction, between the first semiconductor chip and the second semiconductor chip is about 6 mm or less.

19. The display device of claim 16, wherein a thickness, in a vertical direction, of the interposer film is about 30 μm to about 40 μm.

20. The display device of claim 16, wherein
the first semiconductor chip and the second semiconductor chip do not overlap with each other in a vertical direction with respect to the second surface of the lower base film, and
at least part of the first semiconductor chip overlaps with the second semiconductor chip in a horizontal direction, which intersects the vertical direction.
